(19) United States
(12) Patent Application Publication
(10) Pub. No.: US 2009/0061357 A1
(43) Pub. Date: Mar. 5, 2009

(54) IONIC POLYMER PARTICLES FOR PROCESSLESS PRINTING PLATE PRECURSOR

(75) Inventor: Yisong YU, Richmond (CA)

Correspondence Address: YISONG YU, 6391 GOLDSMITH DRIVE, RICHMOND, BC, V7E-4G6, CA

(73) Assignee: Yisong Yu, Richmond (CA)

(21) Appl. No.: 12/192,206

(22) Filed: Aug. 15, 2008

Related U.S. Application Data
(60) Provisional application No. 60/969,626, filed on Sep. 2, 2007.

(51) Int. Cl. G03F 7/00

(52) U.S. Cl. 430/286.1; 430/270.1

(57) ABSTRACT

A processless lithographic printing precursor comprising a substrate, a layer of imaginable element on the substrate. The imaginable element comprising: (1) a substance capable of converting radiation into heat; (2) anionic polymer particles and (3) cationic polymer particles. The imaginable element can not be removed by water or fountain used for press when coated and dried, and becomes hydrophobic under the action of heat. The converter substance may be selected to have an absorption spectrum that is optimized to absorb at the wavelength of imaging radiation. The anionic polymer particles have an anionic surface and cationic polymer particles have a cationic surface. The processless lithographic printing precursor so created may be imaged using absorbed radiation that is imagewise converted to heat, resulting in areas of hydrophobic property, while unimaged areas retain their hydrophilic property. This allows the latent image so formed to be employed in creating a negative-working lithographic printing master. The negative-working lithographic printing master so created is irreversible, does not require a substrate of controlled hydrophilicity and provides great toughness in the exposed areas.

### CROSS-REFERENCE TO RELATED APPLICATION

This application claims the benefit of provisional application No. 60/969,626 filed on Sep. 2 2007.

### FIELD OF THE INVENTION

This invention relates to a negative-working thermal lithographic printing plate precursor and in particular to image formation in printing plates without a wet washing-off process.

### BACKGROUND OF THE INVENTION

Planographic or lithographic printing is the process of printing from specially prepared planar surfaces, some areas of which are capable of accepting lithographic ink or oil, whereas other areas, when moistened with water, will not accept the ink or oil. The areas which accept ink or oil form the printing image areas and the areas which reject the ink or oil form the background areas.

Photosensitive compositions have been widely employed in areas such as printed circuit board (PCB) and lithographic printing plate. Typically these compositions are coated as a layer onto a substrate, dried and/or cured, forming an imaginable element, and then imagewise irradiated with suitable radiation or particle beams. Subsequent to irradiation the irradiated area could have different properties from the unirradiated areas. In some cases the imagewise irradiation directly causes the irradiated areas to be removed or ablated. In other cases the chemical behavior of the irradiated area is changed by the irradiation process, one example being that the irradiated area could become more or less soluble in a suitable liquid than an unirradiated area. In yet other cases the irradiated area changes its affinity for some or other liquid, typically either ink, oil, water or fountain solution, as compared with the unirradiated areas.

Planographic or lithographic printing is the most commonly used form of printing today. Lithographic printing involves creating printing and non-printing areas on a suitable planar lithographic printing plate precursor, substantially on a common planar surface. Printing and non-printing areas could be arranged with imagewise irradiation to have different affinities for printing ink and or water. When the areas of the coating not irradiated ultimately form the printing areas of the image, then the precursor is referred to as “positive working”. Conversely, when the printing area is established by the aforementioned irradiation or the particle beam, then the lithographic printing plate precursor comprising the substrate and the dried and or cured layer of imageable composition is referred to as being “negative working”.

In a conventional process for producing lithographic printing plate or printed circuit board, a film original is placed on an imaginable element layer. The layer is then irradiated through the original with ultraviolet and/or visible light. Such method of working is cumbersome and labor intensive. In last ten years, laser direct imaging methods (LDI) have been widely developed and applied for producing lithographic printing plate or printed circuit board on the basis of digital data from a computer without requiring the intermediate processing of a photographic film. LDI offers many advantages such as line quality, just-in-time processing, improved manufacturing yields, elimination of film costs, and other recognized benefits.

For thermal image process, the imaging may be performed by direct heating of the media, such as by means of a thermal head or a thermal nib or pen. More typically, a non-contact method, such as imaging by means of a light source, is preferred. In such methods, light is first absorbed and turned into heat, and the resultant heat is then used to drive the relevant thermal process. In principle, light of any wavelength may be used in this way to image a so-called thermally sensitive lithographic printing plate.

Recently the use of infra-red wavelengths of light generated either by YAG lasers or, more recently, 800-900 nm radiation from high power Group III-V laser diodes and diode arrays has increased radically. By employing these infrared wavelengths of light, the dark room handling of undeveloped plates is obviated. Even though infrared wavelengths of light are used for imaging in this case, this light still has to be converted to heat in order to drive the thermal process.

In conventional positive working processed plates, the imaginable element layer contained quinonediazide compound, the solubility of the alkali-soluble resin in the alkali developer is suppressed by the presence of the quinonediazide compound. On the other hand, by the irradiation of ultraviolet light, the quinonediazide compound will be photochemically decomposed to form indenecarboxylic acid, whereby the above solubility-suppressing effect will be lost, and the solubility of the above photosensitive layer in the alkali developer will rather be improved. Namely, the positive image-forming mechanisms of the photosensitive layer containing the quinonediazide compound is attributable to the difference in solubility as between the exposed portion and the non-exposed portion due to the chemical change as described above.

Printing plate having an imaginable element layer containing an alkali-soluble resin and a quinonediazide compound on a substrate has been known as a positive lithographic printing plate capable of forming a positive image by irradiation of ultraviolet light through a silver salt masking film original, followed by development by means of an aqueous alkali solution.

However, the conventional positive lithographic printing plate having an imaginable element layer containing a quinonediazide compound has had a drawback that it must be handled under yellow light, as it has sensitivity to ultraviolet light. Furthermore they have a problem of sensitivity in view of the storage stability and they show a lower resolution. The heat mode printing plate precursors are replacing the photosensitive mode printing plate precursors.

In the production of negative-working lithographic printing plates, a hydrophilic support is coated with a thin layer of a negative-working imaginable element. Typical coatings for this purpose include light-sensitive polymer layers containing diazo compounds, dichromate-sensitized hydrophilic colloids and a large variety of synthetic photopolymers. Diazo-sensitized systems in particular are widely used. Imagewise irradiation of such imageable light-sensitive layers renders the irradiated image areas insoluble while the unirradiated areas remain soluble in a developer liquid. The plate is then developed with a suitable developer liquid to remove the imaginable layer in the unirradiated areas.

There are basically two imaging mechanisms that are employed in negative-working lithographic plates. One of these is based on photochemical processes within the imaginable element. In this respect these plates are not unlike photographic media. The photochemical process used renders the imaginable element hardened in the irradiated area. Another, more recent, approach is to make use of thermal processes. In this approach, the imaginable coating on the plate is hardened in the irradiated area by virtue of any one of number of thermal processes. These vary from thermally driven polymerization or crosslinking, to the coalescence or fusing of polymer particles.

One of the most popular approaches to obtain a negative-working lithographic printing plate based on this thermal mechanism is to employ a catalytic reaction. A suitable photo-acid generator is added to the composition of the imaginable element layer of this plate. Various other additives and agents, such as bulk fillers, surfactants, stabilizers and colorants may be added as required. When the plate is irradiated, a latent image is produced in the plate in terms of a distribution of generated acid. Upon subsequent heating before development, known as “pre-heating”, this acid proceeds to crosslink selected materials in the plate to produce imagewise distributed aqueous alkali-insoluble areas in the sensitive coating of the plate. Upon exposure to a suitable aqueous alkaline developer, the non-irradiated areas, which remain soluble in developer solution, are then removed. Upon mounting on a suitable press, the plate is exposed to aqueous fountain solution, which preferentially wets the hydrophilic lithographic base, thereby leaving the hydrophobic crosslinked areas to accept ink.

A known proposed improvement on this “pre-heat” concept, involves obviating the pre-heating step. One approach to a “no-preheat” negative-working infrared-sensitive lithographic plate is based on the free radical initiated polymerization of ethylenically unsaturated compounds.

The radiation sensitive layer on the plate is an infrared light-sensitive mixture comprising a free radical polymerizable system consisting of at least one component selected from ethylenically unsaturated monomers and oligomers and an initiator system including a) at least one compound capable of absorbing IR radiation, and b) at least one compound capable of producing free radicals. During irradiation the IR absorber absorbs the IR radiation, transfers the energy (in form of heat or photons) to the initiator, which then forms the free radicals which, in turn, will initiate the polymerization of the ethylenically unsaturated compounds.

While a number of different systems operating on the basis of this no-preheat principle have been proposed, these systems tend to be marred by inadequate development latitude, limited run-length, insufficient sensitivity in the IR, or poor latent image stability. Development latitude, in a negative-working system, refers to the degree to which the non-irradiated parts of the plate are removed by a given developer of fixed activity, without the developer removing any material in the imaged areas, while run-length refers to the number of impressions that may be printed with a lithographic plate of this type. There remains a requirement for a no-preheat negative-working radiation-sensitive plate with good development latitude and good run-length.

JP-A-60-61 752 discloses an attempt to eliminate the need for a film origin and to obtain a printing plate directly from computer data. Because the photosensitive coating is not sensitive enough to be directly exposed with a laser, it was proposed to coat a silver halide layer on top of the imaginable element coating. The silver halide may then directly be exposed by means of a laser under the control of a computer. Subsequently, the silver halide layer is developed leaving a silver image on top of the imaginable element coating. That silver image then serves as a mask in an overall exposure of the imaginable element coating. After the overall exposure the silver image is removed and the imaginable element coating is developed. Such method has the disadvantage that a complex development and associated developing liquids are needed.

Another attempt has been made wherein a metal layer or a layer containing carbon black is covered on an imaginable element coating. This metal layer or a layer containing carbon is then ablated by means of a laser so that an image mask on the imaginable element layer is obtained. The imaginable element layer is then overall exposed by UV-light through the image mask. After removal of the image mask, the imaginable element layer is developed to obtain a printing plate. Such method is disclosed in for example GB-1 492 070, but still has the disadvantage that the image mask has to be removed prior to development of the imaginable element layer by a cumbersome processing.

U.S. Pat. No. 5,340,699 describes a negative working IR-laser recording imaging element. The IR-sensitive layer comprises a resole resin, a novolac resin, a latent Bronsted acid and an IR-absorbing substance. The printing results of a lithographic plate obtained by irradiating and developing said imaging element are poor.

EP784233 discloses a negative chemical amplification type photosensitive composition comprising a resin selected from novolak and a polyvinylphenol, an amino compound derivative capable of crosslinking the resin, an infrared light-absorbing agent having a specific structure, and a photo-acid-generator.

The performance of such techniques may be not practically adequate. For example, in a case of a negative photosensitive material which requires heat treatment after exposure, it is considered that an acid generated from the exposure acts as a catalyst, and that the crosslinking reaction proceeds during the heat treatment, to form a negative image. However, in such a case, the stability of the image quality was not necessarily satisfactory, due to variation of the treating conditions. On the other hand, in a case of a positive photosensitive material which does not require such heat treatment after exposure, the contrast between an exposed portion and a non-exposed portion was inadequate. Consequently, the non-image portion was not sufficiently removed, or the film-remaining ratio at the image portion was not sufficiently maintained. Further, the printing resistance was not necessarily adequate.

Positive-working direct laser addressable lithographic printing precursors based on phenolic resins sensitive to UV, visible and/or infrared radiation have been described in U.S. Pat. No. 4,708,925, U.S. Pat. No. 5,372,907, U.S. Pat. No. 5,491,046, U.S. Pat. No. 5,840,467, U.S. Patent 5,962,192 and U.S. Pat. No. 6,037,085,

U.S. Pat. No. 4,708,925 discloses a lithographic printing plate provided with a imaginable element layer containing phenolic resin and onium salt, such as triphenylsulfoniumhexafluoro-phosphate with the native solubility of the resin being restored upon photolytic decomposition of the onium salt. This composition may optionally contains an IR-sensitizer. After image-wise exposing said imaging element to UV -visible-or IR-radiation followed by a development step with an aqueous alkali liquid there is obtained a positive or negative working printing plate. The printing results of a lithographic plate obtained by irradiating and developing said imaging element are poor.

U.S. Pat. No. 5,372,907 and U.S. Pat. No. 5,491,046 disclose a radiation-sensitive composition especially adapted to prepare a lithographic printing plate that is sensitive to both ultraviolet and infrared radiation and capable of functioning in either a positive-working or negative-working manner is comprised of a resole resin, a novolac resin, a latent Bronsted acid and an infrared absorber. The solubility of the composition in aqueous alkaline developing solution is both reduced in irradiated areas and increased in unirradiated areas by the steps of imagewise irradiation to activating radiation and heating. The printing results of a lithographic plate obtained by irradiating and developing said imaging element are poor.

In newer generation of positive working processed plates, polymers are chosen that have a tendency for hydrogen bonding, either with themselves or with other additives. The hydrogen bonding is employed to render the otherwise aqueous alkaline soluble polymer less soluble. When irradiated, the hydrogen bonding is disrupted and the polymer becomes, at least temporarily, more soluble in the developer. Again light-to-heat-converter substances may be added to drive the process using selected wavelengths of light and additional inhibitor substances may be added to shift the baseline of the inhibition process.

U.S. Pat. No. 5,840,467 describes a positive working image recording material, which comprises a binder, a light-to-heat converter substance capable of generating heat by the absorption of infrared rays or near infrared rays, and a heat-decomposable substance capable of substantially lowering the solubility of the material when the substance is in the undecomposed state. Specific examples of the heat-decomposable substance include diazonium salts and quinonediazides. Specific examples of the binder include phenolic, acrylic and polyurethane resins. Various pigments and dyes are given as potential light-to-heat converter substances, including specifically cyanine dyes. The image recording material may be coated onto suitable substrates to create an imaginable element. Elements so created may be imagewise irradiated with laser light and the irradiated areas removed with an alkaline developer.

In U.S. Pat. Nos. 5,962,192 and 6,037,085, thermal laser-sensitive compositions are described based on azide-materials wherein a dye component is added to obtain the requisite sensitivity.

For many years, it has been a goal of the printing industry to form printing images directly from an electronically composed digital database, for example, by a so-called “computer-to-plate” system. The advantages of such a system over the traditional methods of making printing plates are the elimination of the costly intermediate silver-containing film and processing chemicals; a saving of time; and the ability to automate the system with consequent reduction in labor costs.

The introduction of laser technology provided the first opportunity to form an image directly on a printing plate precursor by directing a laser beam at sequential areas of the printing plate precursor and modulating the beam so as to vary its intensity. In this way, radiation sensitive plates comprising a high sensitivity photocrosslinkable polymer coating have been exposed to imagewise distributions of radiation from various laser sources and electrophotographic printing plate precursors having sensitivity ranging from the visible spectral region into the near infra-red region (including thermal sensitivity) have been successfully exposed using low powered air-cooled argon-ion lasers and semiconductor laser devices.

While lithographic printing precursors post-exposure developable using aqueous media, preferably alkaline aqueous media, are well known and widely used in the printing industry, there is a more specific subset of precursors that may be developed on press by the action of the fountain solution employed during wet offset printing. A newer class of lithographic media is based upon the general concept of employing polymeric particles in an otherwise hydrophilic binder, often along with a substance to convert light into heat. This kind of media is exemplified by U.S. Pat. No.6,001,536. The unirradiated areas of a lithographic precursor based on this generic media may be removed by treatment with fountain solution on a printing press. This kind of precursor is therefore pseudo-processless, in that no specific separate development step with a specific developer, as such, is required to obtain a master. The imagewise irradiated areas are rendered hydrophobic and hence the master is in effect negative-working. These precursors allow lithographic printing masters to be made relatively easily on-press. The quality of the printed image rendered is directly dependent on the choice and quality of hydrophilic substrate used, as this substrate is exposed and has to carry the fountain solution during the wet offset printing process.

U.S. Pat. No.3,476,937 described a basic heat mode printing plate or thermal printing plate precursor in which particles of thermoplastic polymer in a hydrophilic binder coalesce under the influence of heat, or heat and pressure, that is image-wise applied. The fluid permeability of the material in the exposed areas is significantly reduced. This approach forms the basis of heat-based lithographic plates that are developed using various aqueous media. The later U.S. Pat. No. 3,793,025 described the addition of a pigment or dye for converting visible light to heat, after which essentially the same process is followed as in the earlier disclosure. In U.S. Pat. No. 3,670,410 interlayer structures based on the same principles are presented. U.S. Pat. No. 4,004,924 described the use of hydrophobic thermoplastic polymer particles in a hydrophilic binder together with a material to convert visible light to heat. This combination is employed to generate printing masters specifically by flash exposure.

These early works have formed the basis of commercial lithographic products. However, this work did not address the inherent problems associated with the use of lithographic plates sensitive to visible wavelengths of light under the practical conditions of commercial printing. These early works were performed at a time when digital-on-press technology had not yet been developed. The patents therefore did not anticipate many of the considerations typical of this newer technology wherein data is written point for point directly to the imaging surface by a point light source or combination of such sources such as laser arrays, and the imaging surface is developed on-press.

Since the basic offset printing process requires fountain solution to wet the printing surface before inking, much effort has been put into ensuring that on-press media may be developed using the same fountain solution or at least an aqueous liquid. There is, however, a trade-off between durability of the imaged printing surface and its developability. If the surface is easily developed, it is often not very durable. This durability limitation is thought to be due to the abrasive action of the pigments employed in offset inks coupled with the physical interaction between the blanket cylinder and the plate master cylinder that results in relatively rapid wear of the hydrophobic image areas of the printing plate.

As pointed out in U.S. Pat. No. 6,001,536, these newer technological issues were addressed to some degree by Research Disclosure No. 33303 of January 1992. This document discloses a heat-sensitive imaging element comprising, on a support, a cross-linked hydrophilic layer containing thermoplastic polymer particles and an infrared absorbing pigment such as e.g. carbon black. By image-wise exposure to an infrared laser, the thermoplastic polymer particles are image-wise coagulated thereby rendering the surface of the imaging element at these areas ink accepting without any further development. A disadvantage of this method is that the printing plate so obtained is easily damaged since the non-printing areas may become ink-accepting when some pressure is applied thereto. Moreover, under critical conditions, the lithographic performance of such a printing plate may be poor and accordingly such printing plate has little lithographic printing latitude.

Subsequent development of the technology along the above lines has produced a considerable body of art largely teaching various single- and multi-layered structures based on hydrophobic polymer particles in a hydrophilic binder combined, either in the same layer or separate layers, with a material to convert light to heat. A variety of individual polymers, light-to-heat-converters and hydrophilic binders have been proposed. Examples of these media and some aspects of their on-press imaging and processing are provided by U.S. Pat. Nos. 6,001,536, 6,030,750, 6,096,481 and 6,110,644. U.S. Pat. No. 5,816,162 provides an example of a multilayer structure that may be imaged and processed on-press. Fundamentally, these developments have all been improvements on the basic approach set out by U.S. Pat Nos. 3,476,937 and 4,004,924.

These developments all have one factor in common. The printing surfaces produced by these materials provide run-lengths (number of printing impressions per plate) of the order of 20,000 to 30,000 impressions per prepared printing surface on good quality paper. This is rather shorter than the run-lengths achievable with some other kinds of media used in industry. The cause of this may be traced directly to the developability versus durability trade-off raised earlier. The commercially available thermal media also does not function well with lower quality uncoated paper or in the presence of some commonly used press-room chemicals such as set-off powder, reducing the run-length often to less than one third of that achieved under ideal conditions. This is unfortunate in that these materials and lower quality paper are both inherent realities of the commercial printing industry.

The literature reveals a variety of alternate approaches. Examples include coatings comprising core-shell particles, softenable particles or various functional layers. These alternative approaches also suffer from endurance problems during printing and/or from reduced ink uptake. In particular, it has been disclosed in U.S. Pat. No. 4,731,317, based on an alternative body of work, that non-film-forming polymer emulsions such as LYTRON 614, which is a styrene based polymer with a particle size on the order of 1000 Angstroms, can be used, alone or with an energy absorbing material such as carbon black, to form an image according to that particular invention. In the embodiment of that invention, the polymer emulsion coating is not light sensitive but the substrate used therein converts laser radiation so as to fuse the polymer particles in the image area. In other words, the glass transition temperature (Tg) of the polymer is exceeded in the imaged areas thereby fusing the image in place onto the substrate. The background can be removed using a suitable developer to remove the non-laser illuminated portions of the coating. Since the fused polymer is ink loving, a laser imaged plate results without using a light sensitive coating such as diazo. However, there is a propensity for the background area to retain a thin layer of coating in such formulations. This results in toning of the background areas during printing.

Operations involving off-press imaging and manual mounting of printing plates are relatively slow and cumbersome. On the other hand, high speed information processing technologies are in place today in the form of pre-press composition systems that can electronically handle all the data required for directly generating the images to be printed. Almost all large scale printing operations currently utilize electronic pre-press composition systems that provide the capability for direct digital proofing, using video displays and visible hard copies produced from digital data, text and digital color separation signals stored in computer memory. These pre-press composition systems can also be used to express page-composed images to be printed in terms of rasterized, digitized signals. Consequently, conventional imaging systems in which the printing images are generated off-press on a printing plate that must subsequently be mounted on a printing cylinder present inefficient and expensive bottle-necks in printing operations.

On-press imaging is a newer method of generating the required image directly on the plate or printing cylinder. Existing on-press imaging systems can be divided into two types.

In the first type a blank plate is mounted on the press and imaged once, thus requiring a new plate for each image. An example of this technology is the well-known Heidelberg Model GTO-DI, manufactured by the Heidelberg Druckmaschinen AG (Germany). This technology is described in detail in U.S. Pat. No. 5,339,737. The major advantage compared to off-press plate making is much better registration between printing units when printing color images.

With press imaging systems that use plates, whether imaged off-press or on-press, the mounting cylinder is split so that clamping of the ends of the plate can be effected by a clamping means that passes through a gap in the cylinder and a slit between the juxtaposed ends of the plate. The gap in the mounting cylinder causes the cylinder to become susceptible to deformation and vibration. The vibration causes noise and wears out the bearings. The gap in the ends of the plate also leads to paper waste in some situations.

To address these issues of wear and paper waste, there has been much focus on creating a second type of on-press imaging system that will allow the coating of the very printing cylinder itself, or a sleeve around it, with an appropriate thermal medium working by the principles outlined above. An example of this approach is given in U.S. Pat. No. 5,713,287, which also describes the spraying of media onto the printing surface while the printing surface is mounted on the press.

In the case of both types of on-press imaging systems the overall process has the same elements. The printing surface, whether plate or cylinder or sleeve, is cleaned. It is then coated with the thermal medium. The coating is then cured or dried to form a hydrophilic layer or one that can be removed by fountain or other aqueous solutions. This layer is then imaged using data written directly, typically via a laser or laser array. This process makes the polymeric particles coalesced in the irradiated areas, leaving the irradiated areas hydrophobic or resistant to removal. The printing surface is then developed using an appropriate developer liquid. This includes the possibility of using fountain solution. The coating in the unirradiated areas is thereby removed, leaving the irradiated hydrophobic areas. The printing surface is then inked and the ink adheres only to the hydrophobic imaged and coalesced areas, but not to the irradiated areas of the hydrophilic substrate where there is water from the fountain solution, thereby keeping the ink, which is typically oil-based, from adhering. Printing is now performed. At the end of the cycle, the imaged layer is removed by a solvent and the process is restarted.

A more specific category of lithographic precursors employs mechanisms and compositions that cause the sensitive layer on the substrate to switch between hydrophilic and hydrophobic, without any material being required to be removed with a development step. That is, there is no removal of material at all, even by fountain solution. These are true processless precursors.

U.S. Pat. No. 6,410,202 describes a composition for thermal imaging comprising a hydrophilic heat-sensitive polymer having recurring ionic groups within the polymer backbone or chemically attached thereto. The imaging members of this particular invention do not require post-imaging wet processing and are generally negative-working in nature. In some cases, the polymers are crosslinked upon exposure and provide increased durability to the imaging members. In other and preferred cases, the polymers are crosslinked upon application to a support and curing. A further example of this class of precursor is provided by U.S. Pat. No. 5,985,514. That patent describes an imaging member that is composed of a hydrophilic imaging layer having a hydrophilic heat-sensitive polymer containing heat-activatable thiosulfate groups, and optionally a photothermal conversion material. Upon application of energy that generates heat, such as from IR irradiation, the polymer is crosslinked and rendered more hydrophobic. The exposed imaging member can be contacted with a lithographic printing ink and a fountain solution and used for printing with or without post-imaging wet processing. U.S. Pat. No. 4,081,572 describes making hydrophilic printing masters comprising coating a self-supporting master substrate with a specific hydrophilic polymer containing carboxylic acid functionality and selectively converting this polymer in image configuration to a hydrophobic condition by heat. The polymer is selectively converted to a hydrophobic condition in image configuration through heat-induced cyclodehydration reactions. In other examples the precursor is inherently positive-working, as in the case of U.S. Pat. No. 4,634,659. That particular patent describes a method of making a processing-free planographic printing plate comprising irradiating a plate surface comprised of a hydrophobic organic compound capable of being converted, upon exposure to radiation, from hydrophobic to hydrophilic, carrying out the exposure in an image pattern, thereby selectively converting said surface, in the image pattern, from hydrophobic to hydrophilic, thereby making the precursor positive-working.

A yet more specific category of true processless lithographic precursors, is based on media comprising polymer-based particles or microcapsules:

In U.S. Pat. No. 6,550,237 a heat-sensitive material is described for making a negative working non-ablative lithographic printing plate including in a heat sensitive layer thermoplastic polymer beads and a compound capable of converting light into heat on a surface of a hydrophilic metal support. The layer is free of binder, and is characterized in that the thermoplastic polymer beads have a diameter between 0.2 .mu.m and 1.4 .mu.m. Argument is provided for the requirement that the thermoplastic particles should have a specific size range. It is explained that, when the polymer particles are subjected to a temperature above the coagulation temperature they coagulate to form a hydrophobic agglomerate so that at these parts the metallic support becomes hydrophobic and oleophilic. Preferably, the polymer particles are selected from the group consisting of polyvinyl chloride, polyvinylidene chloride, polyacrylonitrile, polyvinyl carbazole etc., copolymers or mixtures thereof. Most preferably used are polystyrene, polyacrylate or copolymers thereof and polyesters or phenolic resins. No indication is given that the polymer particles should be hydrophilic, or that there may be more than one polymer in the particles.

In European Patent Application No. EP01057622, a lithographic printing plate precursor requiring no development step is described. It comprises a support, having provided thereon a layer comprising a hydrophilic medium, wherein the layer comprising a hydrophilic medium contains a hydrophobitization precursor having a hydrophilic surface and a light/heat converting agent which is hydrophilic in itself, or at least on the surface. Various implementations of the invention are presented in which the hydrophobitization precursor having a hydrophilic surface is a particle dispersion of composite constitution containing a hydrophobic substance at the core part and having a surface layer of specifically superficial hydrophilicity. All forms of particles disclosed are composed of either one or two distinct materials. Various materials may be at the core, including hydrophobic polymeric materials and crosslinking materials. A light-to-heat converting material, which is specifically chosen to be hydrophilic, is also added.

U.S. Pat. No. 5,569,573 describes a thermosensitive lithographic printing original plate comprising a substrate, a hydrophilic layer containing a hydrophilic binder polymer, and a microcapsuled oleophilic material which forms an image area by heating; the hydrophilic binder polymer having a three-dimensional cross-link and a functional group which chemically combines with the oleophilic material in the microcapsule when the microcapsule is ruptured, and the microcapsuled oleophilic material having a functional group which chemically combines with the hydrophilic binder polymer when the microcapsule is ruptured. Among the many hydrophilic binder polymers listed are polysaccharides.

There remains a requirement for negative-working true processless lithographic precursors having long run-length, suitable sensitivity to laser-diode-based imaging radiation, and which are easy to prepare, preferably from aqueous media.

### SUMMARY OF THE INVENTION

A processless lithographic printing precursor comprising a substrate, a layer of imaginable element on the substrate. The imaginable element comprising: (1) a substance capable of converting radiation into heat; (2) anionic polymer particles and (3) cationic polymer particles. The imaginable element can not be removed by water or fountain used for press when coated and dried, and becomes hydrophobic under the action of heat. The anionic polymer particles have an anionic surface and cationic polymer particles have a cationic surface.

The imaginable element further may comprise a substance capable of converting radiation into heat. The converter substance may be selected to have an absorption spectrum that absorbs at the wavelength of imaging radiation. While the sensitivity of the imaginable element is not limited to any particular radiation, the preferred form of radiation is electromagnetic, and preferred wavelengths of radiation-sensitivity are between 700 nm and 1300 nm, more preferably between 700 nm and 1000 nm.

The imaginable element can form a hydrophilic layer on a substrate but it can not be removed by water or fountain used for press when coated and dried. The hydrophilic imaginable element layer becomes hydrophobic under the action of heat. The imaginable element may be provided as a coatable composition to be applied to substrates to form a processless lithographic printing precursor. The processless lithographic printing precursor so created may be imaged using absorbed radiation that is imagewise converted to heat, resulting in areas of hydrophobic property, while unimaged areas retain their hydrophilic property. This allows the latent image so formed to be employed in creating a negative-working lithographic printing master. The negative-working lithographic printing master so created is irreversible, does not require a substrate of controlled hydrophilicity and provides great toughness in the exposed areas during action of printing. The imaginable element may be coated on-platesetter or on-press onto a suitable substrate, including the drum of the press. The imaginable element of the present invention may be coated off-press on a suitable substrate to create a pre-coated processless lithographic printing precursor.

### DETAILED DESCRIPTION OF THE PREFERRED EMBODIMENTS

In a first aspect of the invention there is provided an imaginable element comprising both anionic polymer particles and cationic polymer particles. The anionic polymer particles have an anionic surface and cationic polymer particles have a cationic surface. The imaginable element further may comprise a substance capable of converting radiation into heat. The imaginable element can form a hydrophilic layer on a substrate but it can not be removed by water or fountain used for press when coated and dried. The hydrophilic imaginable element layer becomes hydrophobic under the action of heat.

In a first embodiment of the present invention, an imaginable element comprises anionic polymer particles and cationic polymer particles. The anionic polymer particles have an anionic surface and cationic polymer particles have a cationic surface. A substance capable of converting radiation into heat is preferably added to the composition to create the imaginable element.

In yet a further aspect of the invention, the imaginable element can not be removed by water or fountain used for press when coated and dried, and becomes hydrophobic under the action of heat. The imaginable element may be provided as a coatable composition to be applied to substrates to form a processless lithographic printing precursor. The processless lithographic printing precursor so created may be imaged using absorbed radiation that is imagewise converted to heat, resulting in areas of hydrophobic property, while unimaged areas retain their hydrophilic property. This allows the latent image so formed to be employed in creating a negative-working lithographic printing master. The negative-working lithographic printing master so created is irreversible, does not require a substrate of controlled hydrophilicity and provides great toughness in the exposed areas. The imaginable element may be coated on-platesetter or on-press onto a suitable substrate, including the drum of the press. The imaginable element of the present invention may be coated off-press on a suitable substrate to create a pre-coated processless lithographic printing precursor.

In one embodiment of the invention, the coatable compositions comprise anionic polymer particles and cationic polymer particles in aqueous carriers. In this embodiment, the composition may also contain additives to assist in the imaging steps and/or the coating steps. For example, a substance capable of converting the imaging radiation into heat is particularly desirable in the compositions so that the imaging radiation is efficiently absorbed and converted to heat. The substance capable of converting radiation to heat may be a pigment, such as, but not limited to, carbon black, or a dye. Infrared and near infrared (NIR) dyes are particularly suitable for use with infrared (IR) lasers.

In a preferred embodiment of the present invention the substance capable of converting radiation to heat absorbs radiation over the range 700 nm to 1200 nm, more preferably over the range 800 nm to 1100 nm, and most preferably over the range 800 nm to 850 nm, and converts it to heat. Examples of such substances are polymethine type coloring material, a phthalocyanine type coloring material, a dithiol metallic complex salt type coloring material, an anthraquinone type coloring material, a triphenylmethane type coloring material, an azo type dispersion dye, and an intermolecular CT coloring material. The representative examples include N-[4-[5-(4-dimethylamino-2-methylphenyl)-2,4-pentadienylidene]-3-methyl-2,5-cyclohexadiene-1-ylidene]-N,N-dimethyl-ammonium acetate, N-[4-[5-(4-dimethylaminophenyl)-3-phenyl-2-pentene4-in-1-ylidene]-2,4-cyclohexadiene-1-ylidene]-N,N-dimethylammonium perchlorate, bis(dichlorobenzene-1,2-dithiol)nickel(2:1 )tetrabutyl-ammoni-um and polyvinylcarbazol-2,3-dicyano-5-nitro-1,4-naphthoquinone complex. Some specific commercial products that may be employed as substance capable of converting radiation to heat include Pro-jet 830NP, a modified copper phthalocyanine from Avecia of Blackley, Lancashire in the U.K., and ADS 830A, an infra-red absorbing dye from American Dye Source Inc. of Montreal, Quebec, Canada.

In one embodiment of the invention, anionic polymer particles and cationic polymer particles are made by free-radical polymerization of hydrophobic vinyl monomers in the presence of ionic monomers or polymers. The hydrophobic vinyl monomers of the present invention is selected from electrically neutral ethylenically unsaturated monomers such as ethylene, propylene, styrene, other vinyl monomers (e.g. methyl methacrylate), and electrically neutral derivatives of these ethylenically unsaturated monomers. The term “electrically neutral” is well understood in the art and includes primarily non-polar compounds, although monomers with internal charge distributions and overall electrical neutrality (e.g., Zwitterions) are acceptable.

Preferably, the hydrophobic vinyl monomer of the present invention is selected from one or more of styrene, substituted styrenes, esters of (meth)acrylic acid, vinyl halides, (meth)acrylonitrile, vinyl esters, silicon-containing polymerizable monomers. Suitable examples of esters of (meth)acrylic acid include, but are not limited to, methyl(meth)acrylate, ethyl(meth)acrylate, propyl(meth)acrylate, butyl(meth)acrylate and lauryl(meth)acrylate. Suitable examples of substituted styrenes include, but are not limited to, alpha-methylstyrene and vinyltoluene. Suitable examples of substituted vinyl esters include, but are not limited to, vinyl acetate and vinyl propionate. Suitable examples of vinyl halides include, but are not limited to, vinyl chloride and vinylidene chloride.

The ionic monomer of the present invention is selected from within the classes of water-soluble/dispersible ethylenically unsaturated monomers, especially acryloyl or methacryloyl monomers and anionic-substituted styrene monomers, and especially acryloyl acids (i.e., acrylic acid, and methacrylic and other substituted acrylic acids) and sulfonated or phosphonated styrenes (e.g., with alkali or alkaline metal or ammonium counterions such as Na, Li, K and the like).

Preferably, the ionic monomer of the present invention is selected from one or more of acrylic acid, methacrylic acid, crotonic acid, itaconic acid, fumaric acid, maleic acid, citraconic acid and their salts; monomers having various types of hydroxyl groups, such as 2-hydroxyethyl(meth)acrylate, 2-hydroxypropyl(meth)acrylate, 4-hydroxybutyl(meth)acrylate, monobutylhydroxyl fumarate and monobutylhydroxyl itaconate; various types of nitrogen-containing vinyl monomers such as (meth)acrylamides, diacetone acrylamides, N-methylol acrylamides; sulphonamide-or phosphorus-containing vinyl monomers; various types of conjugated dienes such as butadiene; dicarboxylic acid half-esters of hydroxyl group-containing polymers, such as phthalic, succinic or maleic acid half esters of a polyvinyl acetal and, in particular, of a polyvinyl butyral; and alkyl or aralkyl half esters of styrene-or alkyl vinyl ether-maleic anhydride copolymers, in particular alkyl half esters of styrene-maleic anhydride copolymers.

The ionic polymer of the present invention is preferably selected from saccharide (such as cellulose, starch or chitosan), polyethyleneimine resins, polyamine resins (for example polyvinylamine polymers, polyallylamine polymers, polydiallylamine resins and amino(meth)acrylate polymers), polyamide resins, polyamide-epichlorohydrin resins, polyamine-epichlorohydrin resins, polyamidepolyamine-epichlorohydrin resins, as well as dicyandiamide-polycondensation products (for example, polyalkylenepolyamine-dicyandiamide copolymers), and polyvinylpyrolidone.

In one embodiment of the invention, the imaginable element optionally comprises surfactants, plasterizer, hydrophilic lubricants and fillers (e.g., silica, titania, zinc oxide, zirconia, etc.).

The specific term substrate is used here to describe the base onto which the imaginable element is coated. The substrate material used depends upon the purpose for which the image is to be used and may be, for example, formed of metal, polymer material (such as, but not limited to, PET), paper, ceramic, or composite material The substrates used in accordance with the present invention are preferably formed of aluminum, zinc, steel, or copper. These include the known bi-metal and tri-metal plates such as aluminum plates having a copper or chromium layer; copper plates having a chromium layer and steel plates having copper or chromium layers. Other preferred substrates include metallized plastic sheets such as poly(ethylene terephthalate).

Particularly preferred plates are grained, or grained and anodized, aluminum plates where the surface is roughened (grained) mechanically or chemically (e.g. electrochemically) or by a combination of roughening treatments. The anodizing treatment can be performed in an aqueous acid electrolytic solution such as sulphuric acid or a combination of acids such as sulphuric and phosphoric acid.

According to the present invention, the anodized aluminum surface of the substrate may be treated to improve the coating properties of its surface. For example, a phosphate solution that may also contain an inorganic fluoride is applied to the surface of the anodized layer. The aluminum oxide layer may be also treated with sodium silicate solution at an elevated temperature, e.g. 90.degree. C. Alternatively, the aluminum oxide surface may be rinsed with a citric acid or citrate solution at room temperature or at slightly elevated temperatures of about 30 to 50.degree. C. A further treatment can be made by rinsing the aluminum oxide surface with a bicarbonate solution.

Another useful treatment to the aluminum oxide surface is with polyvinylphosphonic acid, polyvinylmethylphosphonic acid, phosphoric acid esters of polyvinyl alcohol, polyvinylsulphonic acid, polyvinylbenzenesulphonic acid, sulphuric acid esters of polyvinyl alcohol, and acetals of polyvinyl alcohols formed by reaction with a sulphonated aliphatic aldehyde. It is evident that these post treatments may be carried out singly or as a combination of several treatments.

According to the present invention, the substrate comprises a flexible support, such as paper or plastic film, provided with a cross-linked hydrophilic layer for better coatability. A suitable cross-linked hydrophilic layer may be obtained from a hydrophilic (co)polymer cured with a cross-linking agent. The hydrophilic (co-) polymers that may be used comprise for example, homopolymers and copolymers of vinyl alcohol, hydroxyethyl acrylate, hydroxyethyl methacrylate, acrylic acid, methacrylic acid, acrylamide, methylol acrylamide or methylol methacrylamide. The cross-linking agents that may be used comprise for example a hydrolysed tetra-alkylorthosilicate, formaldehyde, glyoxal or polyisocyanate.

A cross-linked hydrophilic layer of the substrate preferably also contains materials that increase the porosity and/or the mechanical strength of this layer. Colloidal silica employed for this purpose may be in the form of any commercially available water-dispersion of colloidal silica. The incorporation of these particles causes a roughness, which will improve adhesion of the coating layer on the substrates.

A preferred mode of preparation of the negative-working thermal imaginable element of the present invention is mixing anionic polymer particles and cationic polymer particles in aqueous carrier, the resultant mixture is added with the substance capable of converting radiation. Minor amounts of additives may be added at various stages of preparation. Surfactants can be added (e.g., silicone-polyol) to improve film forming quality when the composition is coated onto a surface. A plasticizer may be added to reduce energy requirement and fillers may be added to increase run length.

In a preferred embodiment, the imaginable element may be applied to the substrate while the latter resides on the press. The substrate may be an integral part of the press or it may be removably mounted on the press. In this embodiment the imaginable element may be cured by means of a curing unit integral with the press, as described in U.S. Pat. No.5,713,287.

Alternatively, the imaginable element coating may be applied to the substrate and cured before the complete lithographic printing precursor is loaded on the printing cylinder of a printing press. This situation would pertain in a case where a lithographic printing plate is made separate from the press or a press cylinder is provided with a lithographic printing surface without being mounted on the press.

In a preferred embodiment of the invention, the imaginable element coating is imagewise converted by means of the spatially corresponding imagewise generation of heat within the coating to form a hydrophobic area corresponding to areas imagewise irradiated. The imaging process itself may be by means of scanned laser radiation as described in U.S. Pat. No. 5,713,287. The wavelength of the laser light and the absorption range of the converter substance are chosen to match each other. The heat to drive the process of converting the irradiated areas of the precursor from hydrophilic to hydrophobic is produced via the substance capable of converting radiation into heat. The imaginable element of the present invention, when coated and dried on a suitable substrate, therefore becomes hydrophobic under the action of heat. During subsequent wet lithographic offset printing, the exposed areas of the imaginable element coating will be hydrophobic and the lithographic printing ink will adhere preferentially to these areas, as water or fountain solution will be adhering to the hydrophilic areas. This makes the processless printing master of the present invention inherently negative-working. The method does not require a substrate of controlled hydrophilicity and provides great toughness in the exposed areas of the precursor, thereby extending the run length of the negative-working lithographic printing master.

Without limiting the scope of the invention in any way, the mechanism by which the irradiated areas of the layer become hydrophobic is believed to be as follows. When the imaginable element layer is imaged, the substance capable of converting radiation into heat provides imagewise distributed heat. This imagewise distributed heat renders the anionic polymer particles and cationic polymer particles to thermally soften and change surface behavior. In the unirradiated areas, where the anionic polymer particles and cationic polymer particles form a non-removable hydrophilic layer from ionic bond which chemically combines both type of polymer particles together, have not been disrupted and distribute across the surface. During wet offset printing, the imaged areas form an oleophilic region on the surface of the layer and take ink, whereas the unirradiated areas of the layer remain hydrophilic and take fountain solution.

The imaging process is irreversible when performed. The areas of the composition exposed to imaging radiation remain hydrophobic and cannot be reversed to form a useable processless radiation-imageable lithographic printing precursor by way of thermal treatment (heating or cooling), radiation treatment to the same or different imaging range of radiation. The imaginable element is not removable by water or fountain-solution when coated and dried. During subsequent inking with an oil-based lithographic ink, the exposed areas of the imaginable element coating will be the areas to which the lithographic printing ink will adhere. This makes possible the subsequent use of the inked surface for the purposes of printing.

While the present invention pertains very directly to the manufacture of lithographic plates, it has particular significance in the process-free practice. In the case of fully on-press practice, where the imaginable element composition is sprayed onto a plate on the printing cylinder, or even on to the printing cylinder itself, there is a considerable list of criteria, all of which are to be met by any lithographic printing precursor that is to meet the needs of industry. The lithographic printing precursor of the present invention meets these criteria.

As is evident, the imaginable element coating and lithographic printing precursors of the present invention allow the combination of the benefits of the anionic polymer particle and cationic polymer particles with the substrate-independence of a switchable polymer approach to plate-making. Ionic bonds which chemically combines both type of polymer particles together demonstrate not only a substantially hydrophilic nature, but also great resistance to water or fountain, therefore it shows reduced scumming, a phenomenon that occurs when the water-bearing area of the master loses some of its hydrophilic nature and starts to take ink. This provides a master with excellent run-length, which is nevertheless producible from an aqueous based imaginable element coating.

### EXAMPLES

The following examples illustrate aspects of the invention.

Preparation of the Substrates

A 0.25 mm thick aluminum sheet was degreased by immersing the sheet in an aqueous solution containing 8 g/l of sodium hydroxide at 40.degree. C. and rinsed with demineralized water. The sheet was then electrochemically grained using an alternating current in an aqueous solution containing 3.5 g/l of hydrochloric acid, 3.5 g/l of hydroboric acid and 4 g/l of aluminum ions at a temperature of 30.degree. C. and a current density of 100 A/m.sup.2 to form a Ra of 0.45 .mu.m.

After demineralized water rinse, the aluminum foil was then immersed in an aqueous solution containing 250 g/l of sulfuric acid at 65.degree. C. for 150 seconds and rinsed with demineralized water at 30.degree. C. for 25 seconds.

The foil was subsequently subjected to anodic oxidation in an aqueous solution containing 250 g/l of sulfuric acid at a temperature of 40.degree. C., a voltage of about 12.5 V and a current density of 200 A/m.sup.2 for about 250 seconds to form an anodic oxidation film of 2.5 g/m.sup.2 of Al.sub.2 O.sub.3 then washed with demineralized water, posttreated with a solution containing polyvinylphosphonic acid, rinsed with demineralized water at 20.degree. C. during 90 seconds and dried.

### Synthesis Examples

### Synthesis Example 1 for Anionic Polymer Particle A-1

15 g acrylic acid, 85 g of styrene and 1 g of potassium persulfate and 1 g of sodium metabisulfite in 700 of water, were added, under nitrogen, into a 1 L glass reactor equipped with thermometer, mechanical stirring, nitrogen inlet and heating bath, set to 60.degree. C. After 6 hours, stirring was stopped and the reactor contents were filtered to give an opaque white liquid which contains 12.5 wt % hydrophilic polymer particles in solid.

### Synthesis Example 2 for Anionic Polymer Particle A-2

85 g acrylic acid, 15 g of styrene and 1 g of potassium persulfate and 1 g of sodium metabisulfite in 700 of water, were added, under nitrogen, into a 1 L glass reactor equipped with thermometer, mechanical stirring, nitrogen inlet and heating bath, set to 60.degree. C. After 6 hours, stirring was stopped and the reactor contents were filtered to give an opaque white liquid which contains 12.5 wt % hydrophilic polymer particles in solid.

### Synthesis Example 3 for Cationic Polymer Particle C-1

15 g chitosan, 85 g of styrene and 1 g of potassium persulfate and 1 g of sodium metabisulfite in 700 of water, were added, under nitrogen, into a 1 L glass reactor equipped with thermometer, mechanical stirring, nitrogen inlet and heating bath, set to 60.degree. C. After 6 hours, stirring was stopped and the reactor contents were filtered to give an opaque white liquid which contains 12.5 wt % hydrophilic polymer particles in solid.

### Synthesis Example 4 for Cationic Polymer Particle C-2

85 g chitosan, 15 g of styrene and 1 g of potassium persulfate and 1 g of sodium metabisulfite in 700 of water, were added, under nitrogen, into a 1 L glass reactor equipped with thermometer, mechanical stirring, nitrogen inlet and heating bath, set to 60.degree. C. After 6 hours, stirring was stopped and the reactor contents were filtered to give an opaque white liquid which contains 12.5 wt % hydrophilic polymer particles in solid.

### Example

### Example 1

A plate was produced by coating the following formulation on to a grained, anodized aluminum plate to give a dry coating weight of 1.2 g/m.sup.2

| Material: | Amount |
|---|---|
| Anionic polymer particle A-1 | 30 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the unimaged area could not be removed by fountain and the plate was fully inked.

### Example 2

A plate was produced by coating the following formulation on to a grained, anodized aluminum plate to give a dry coating weight of 1.2 g/m.sup.2

| Material: | Amount |
|---|---|
| Anionic polymer particle A-2 | 30 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the unimaged area were removed by fountain and the plate did not take the ink.

### Example 3

A plate was produced by coating the following formulation on to a grained, anodized aluminum plate to give a dry coating weight of 1.2 g/m.sup.2

| Material: | Amount |
|---|---|
| Cationic polymer particle C-1 | 30 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the unimaged area could not be removed by fountain and the plate was fully inked.

### Example 4

A plate was produced by coating the following formulation on to a grained, anodized aluminum plate to give a dry coating weight of 1.2 g/m.sup.2

| Material: | Amount |
|---|---|
| Cationic polymer particle C-2 | 30 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the unimaged area were removed by fountain and the plate did not take the ink.

### Example 5

A plate was produced by coating the following formulation on to a grained, anodized aluminum plate to give a dry coating weight of 1.2 g/m.sup.2

| Material: | Amount |
|---|---|
| Anionic polymer particle A-1 | 15 g |
| Cationic polymer particle C-1 | 15 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the unimaged area could not be removed by fountain and the plate was fully inked.

### Example 6

A plate was produced by coating the following formulation on to a grained, anodized aluminum plate to give a dry coating weight of 1.2 g/m.sup.2

| Material: | Amount |
|---|---|
| Anionic polymer particle A-2 | 15 g |
| Cationic polymer particle C-2 | 15 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. It was observed that both the imaged area and the non-imaged area were not removed by fountain but printing could not be performed because the imaged area does not have enough hydrophobicity.

### Example 7

A plate was produced by coating the following formulation on to a grained, anodized aluminum plate to give a dry coating weight of 1.2 g/m.sup.2

| Material: | Amount |
|---|---|
| Anionic polymer particle A-1 | 20 g |
| Cationic polymer particle C-2 | 10 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. The press run was aborted at 1000 impressions without visible degradation of printing quality. At this point the 1% dots of the 200 lines per inch pattern were substantially intact.

### Example 8

A plate was produced by coating the following formulation on to a grained, anodized aluminum plate to give a dry coating weight of 1.2 g/m.sup.2

| | |
|---|---|
| Anionic polymer particle A-2 | 10 g |
| Cationic polymer particle C-1 | 20 g |
| 2 wt % ADS830A in ethanol | 9 g |

After drying at 40 degree C. for 4 minutes, the plate was imaged in a Creo Lotem 400 Quantum with an imaging energy density of 600 mJ/cm² applying a pattern containing a section of resolution equal to 200 lines per inch of varying dot size. The imaged plate was mounted onto a Ryobi 520 press and dampened with fountain solution for 30 seconds before ink was applied to the plate and a press run performed. The press run was aborted at 1000 impressions without visible degradation of printing quality. At this point the 1% dots of the 200 lines per inch pattern were substantially intact.

What is claimed is:

1. A processless lithographic printing precursor comprising a substrate, a layer of imaginable element on the substrate. The imaginable element comprising: (1) a substance capable of converting radiation into heat; (2) anionic polymer particles and (3) cationic polymer particles.

2. The precursor of claim 1, wherein said the imaginable element can not be removed by water or fountain solution used for press when coated and dried.

3. The precursor of claim 1, wherein said the imaginable element is hydrophilic when coated and dried, and becomes hydrophobic under the action of heat.

4. The precursor of claim 1, wherein said the anionic polymer particles have an anionic surface.

5. The precursor of claim 1, wherein said the cationic polymer particles have a cationic surface.

6. The precursor of claim 1, wherein said further comprising a radiation-heat converter.

7. The precursor of claim 4, wherein said the radiation has a wavelength between 700 nm and 1200 nm.

8. The precursor of claim 1, wherein said the substrate is one of a plastic sheet, a paper, a metal plate, a sleeve-less printing press cylinder, and a printing press cylinder sleeve and a flexible support having or having not thereon a cross-linked hydrophilic layer.

9. The precursor of claim 1, wherein said imaginable element optionally comprises surfactants, plasticizers and fillers.

10. The precursor of claim 1, wherein said the anionic polymer particles and cationic polymer particles are made by free-radical polymerization in aqueous. Monomers and initiator, optionally ionic polymers, are added into a reactor. The reaction is carried out under heat for several hours. Particle sizes are controlled by reaction conditions.

11. The precursor of claim 10, wherein said ionic polymers are saccharide (such as cellulose, starch or chitosan), polyethyleneimine resins, polyamine resins (for example polyvinylamine polymers, polyallylamine polymers, polydiallylamine resins and amino(meth)acrylate polymers), polyamide resins, polyamide-epichlorohydrin resins, polyamine-epichlorohydrin resins, polyamidepolyamine-epichlorohydrin resins, as well as dicyandiamide-polycondensation products (for example, polyalkylenepolyamine-dicyandiamide copolymers) and polyvinylpyrolidone.

12. The precursor of claim 1, wherein said the particle sizes of the anionic polymer particles and cationic polymer particles are under 1000 nm, preferred under 500 nm, mostly preferred under 200 nm.
